(19) United States
(12) Patent Application Publication
(10) Pub. No.: US 2009/0153176 A1
(43) Pub. Date: Jun. 18, 2009

(54) Semiconductor device

(75) Inventor: Hideo Inaba, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/314,586

(22) Filed: Dec. 12, 2008

(30) Foreign Application Priority Data
Dec. 13, 2007 (JP) 2007-322019

(51) Int. Cl. G01R 31/26

(52) U.S. Cl. 324/765

(57) ABSTRACT

Disclosed is a semiconductor device including chips having output terminals connected in common to an external terminal. Each of the chips includes a data input and output section that provides a difference during testing between a first driving capability setting the output terminal to a first power supply potential side and a second driving capability setting the output terminal to a second power supply potential side. During testing, the second driving capability is set so as to be higher than the first driving capability. The output signal level from each chip to the terminal equal to the second power supply potential indicates a fail, and the output signal level from each chip to the terminal equal to the first power supply potential indicate a pass. Under this condition, if at least one or more of the multiple chips outputs a fail signal, the second power supply potential is delivered to the external terminal to which the terminals are connected in common. A test method for the semiconductor memory is also disclosed (FIG. 1).

### REFERENCE TO RELATED APPLICATION

This application is based upon and claims the benefit of the priority of Japanese patent application No. 2007-322019 filed on Dec. 13, 2007, the disclosure of which is incorporated herein in its entirety by reference thereto.

### FIELD OF THE INVENTION

This invention relates to a semiconductor device. More particularly, this invention relates to a semiconductor device, having a plurality of chips and a testing method therefor.

### DESCRIPTION OF RELATED ART

Relating to recent DRAMs (Dynamic Random Access Memories) equipped with a large amount of memory capacity, test need a long time to carry out pass/fail decision.

Thus, a variety of test mode methods or techniques that compress data using a mode register set command have so far been proposed (see Patent Documents 1 to 4, for example). Among these, there is such an IO compression technique in which a coincidence detection circuit determines whether or not read data on a plurality of Io lines coincide with one another and the result of decision is delivered on a single terminal. There is also such a technique of even-odd address compression in which a coincidence detection circuit verifies whether or not a plurality of data read out from the memory cell array coincide with one another as to odd and even addresses and the result of decision is output as sole data. With these known techniques, the test time may be shortened for only one chip.

In case an apparatus, on which semiconductor memory devices are mounted, is small-sized, as in the case of a mobile terminal, it is simultaneously required to reduce a device size. For this reason, a multi-chip package (MCP) semiconductor memory, in which a plurality of DRAM chips are mounted on a single package to realize a large capacity and a small device size, has now been developed.

Patent Document 4 discloses a multi-chip package in which, in order to reduce test time, a selection signal that selects one of a plurality of chips and a dummy input signal are entered and in which one or more chips is selected in response to the selection signal or the dummy input signal. The dummy input signal is entered to a dummy input terminal not used by a user. In testing the chips, multiple chips are selected simultaneously and tested to shorten the test time. Patent Document 5 discloses a multi-chip package in which the driving capability is elevated at the wafer test before packaging and in which the driving capability is lowered after packaging to reduce the noise and power consumption.

### [Patent Document 1] JP Patent Kokai JP-A-6-333400

### [Patent Document 2] JP Patent Kokai JP-A-10-223000

### [Patent Document 3] JP Patent Kokai JP-A-2003-132681

### [Patent Document 4] JP Patent Kokai JP-A-2006-191113

### [Patent Document 5] JP Patent Kokai JP-A-2003-110417

### SUMMARY OF THE DISCLOSURE

The following analysis is given from the side of the present invention.

Since a plurality of DRAM chips are mounted in a MCP semiconductor memory, it is necessary to carry out screening (testing) from one chip to another. This elongates a test time of the screening. This problem is now discussed.

FIG. 11 is a timing diagram which is created for analyzing the problems of the MCP semiconductor memory carrying thereon a plurality of DRAM chips. Referring to FIG. 11, chip selection of the two DRAM chips is controlled by chip selection signals CSB1 and CSB2. A command input is valid in case the chip selection signal is active (Low).

In a cycle t1, CSB1 is Low (active) so that a command (CMD) is delivered to a chip (CSB1 chip) to be selected by CSB1.

In the next cycle t2, CSB2 is Low (active) so that a command (CMD) is delivered to a chip (CSB2 chip) to be selected by CSB2.

In cycle t4, CSB1 is Low and read-access (R) of the chip (CSB1 chip) as selected by CSB1 is performed.

In cycle t5, read data is output to a terminal DQ1 of the CSB1 chip, In the same cycle t5, CSB2 is set Low and read-access (R) of the chip (CSB2 chip) as selected by CSB2 is performed.

In cycle t6, read data is output at a terminal DQ2 of the CSB2 chip.

The terminal DQ1 of the CSB1 chip and the terminal DQ2 of the CSB2 chip are connected in common by bonding wires to an MCP's output DQ. Read data of the CSB1 chip and the CSB2 chip are output from the terminal DQ at respective timings shifted by one clock cycle from each other.

Because of the difference in the chip select signals, it is necessary to carry out screening from chip to chip.

It has also been proposed to set a plurality of chips simultaneously to selected states (see Patent Document 4). In this known technique, DQ outputs are connected in common by bonding wires, so that, if, in case the chips are selected simultaneously to read out internal data, one of the multiple chips is a failed chip, output drivers are in contention state, as shown in FIG. 12. The result is that pass/fail decision cannot be made satisfactorily.

Accordingly, it is desirable that when a plurality of chips are set to be in a chip selected states simultaneously and internal data are read out simultaneously from the multiple chips, it is possible to make a pass or fail decision.

The invention seeks to solve one or more of the above problems.

According to one aspect of the present invention, there is provided a semiconductor device comprising a plurality of chips each including a circuit that drives a terminal for outputting a signal, to a first power supply voltage or to a second power supply voltage, depending on the value of a signal to be output. The terminals are coupled together and connected to an external terminal of the semiconductor device. Each chip further includes a circuit for providing a difference between a first driving capability driving the terminal to the first power supply voltage and a second driving capability driving the terminal to the second power supply voltage, responsive to a test signal.

In one embodiment of the present invention, in case at least one of the chips delivers a signal at one of a voltage level of the first power supply voltage and a voltage level of the second power supply voltage to the terminals connected in common, and remaining chips deliver output signals at a voltage level of the other voltage level to the terminals, connected in common, during testing, at the same time as the at least one chip delivers the output signal, a preset one of the first and second power supply voltage levels is output at the external terminal in dependence upon the difference as set between the first driving capability and the second driving capability.

In one embodiment of the present invention, the multiple chips include first and second chips. The first and second chips are set in common, responsive to the test signal, activated during testing, so that the second driving capability is higher than the first driving capability. When one of the first and second chips delivers a signal at the first power supply voltage level to the terminals connected in common and the other chip delivers a signal at the second power supply voltage level to the terminals connected in common, at the same time as the one chip delivers the output signal, the voltage level of the second power supply voltage is output at the external terminal.

In one embodiment of the present invention, responsive to the test signal, the second driving capability is set so as to be higher than the first driving capability. Under the condition that a signal output in each of the chips to the terminal is a fail signal and a pass signal in case the signal level is that of the second power supply voltage and in case the signal level of the signal is that of the first power supply voltage, respectively, the voltage level of the second power supply voltage is output to the terminals connected in common in case at least one of the chips outputs a fail signal.

In one embodiment of the present invention, the semiconductor device includes a driver strength function of variably setting the first driving capability of driving the terminal to the first power supply voltage and the second driving capability of driving the terminal to the second power supply voltage, based on an input command. The semiconductor device also includes means for operating for setting, during testing, responsive to a test signal activated at the time of the testing, by taking advantage of the driver strength function, the first driving capability of driving the terminal to the first power supply voltage at a predetermined first value, and for setting the second driving capability of driving the terminal to the second power supply voltage at a predetermined second value different from the first value.

In one embodiment of the present invention, the chips each include a first set of a plurality of (a n-number of) transistors, connected in parallel between terminals providing the first power supply voltage and the terminal, a second set of a plurality of (a n-number of) transistors, connected in parallel between terminals providing the second power supply voltage and the terminal, and a control circuit. During testing, the control circuit operates, based on the test signal, so that, if a signal supplied to each terminal providing the first power supply voltage is of a first logic value, a predetermined i-number of the n-number of the transistors of the first set, where i is not less than 1 and less than n, are turned on, and so that the n-number of the transistors of the second set are turned off. During the testing, the control circuit also operates, based on the test signal, so that, if a signal supplied to each terminal providing the second power supply voltage is of a second logic value, a predetermined j-number of the n-number of the transistors of the second set, where j is not less than 1 and less than n, are turned on, and so that the n-number of the transistors of the first set are turned off.

In one embodiment of the present invention, the control circuit includes first to n-th logic circuits, having outputs connected to control terminals of an n-number of the transistors of the first set, and first to n-th distinct logic circuits, having outputs connected to control terminals of an n-number of the transistors of the second set. The first logic circuit operates so that, if, out of first to n-th selection signals that select the driving capability, the first selection signal is activated, and the signal delivered to the terminal is of a first logic value, a corresponding first one of the n-number of the transistors of the first set is turned on. The i-th logic circuit, where i is not less than 2 and not more than n, operates so that, if, out of first to n-th selection signals, the i-th selection signal is activated, the signal to be delivered to the terminal is of a first logic value, and the test signal is inactivated, a corresponding i-th transistor out of the n-number of the transistors of the first set are turned on. The i-th logic circuit operates so that, if the test signal is activated, the corresponding i-th transistor out of the n-number of the transistors of the first set is turned off without dependency on the signal to be delivered to the terminals and the i-th selection signal. The i-th distinct logic circuit, where i is not less than 1 and not larger than n, operates so that, in case the test signal is activated, a corresponding i-th transistor out of the n-number of the transistors of the second set is turned on, without dependency on the values of the signal to be supplied to the terminal and a corresponding i-th selection signal out of the first to n-th selection signals. The i-th distinct logic circuit also operates so that, if, with the test signal in inactivated state, the signal to be delivered to the terminal is of a second logic value and the i-th selection signal is in activated state, a corresponding i-th transistor out of the n-number of the transistors of the second set is turned on.

In one embodiment of the present invention, there is provided a semiconductor device comprising a plurality of chips each including a first output transistor that drives a terminal, at least outputting a signal, to a first power supply voltage, and a second output transistor that drives the terminal to a second power supply voltage. The terminals are coupled together and connected to an external terminal of the semiconductor device. Each chip includes a circuit that turns off a predetermined one of the first and second output transistors, during testing, responsive to a test signal.

In one embodiment of the present invention, when the signals are output from the terminals, connected in common, during testing, each terminal assumes one of two states, namely a high impedance state and the voltage level of the first or second power supply.

In one embodiment of the present invention, each chip further comprises a circuit that turns off the predetermined one of the first and second output transistors during a predetermined part of an output period that outputs the signal from the terminal. Each chip according to the present invention further comprises a circuit that forces the one of the first and second output transistors off and forces the other output transistor on during the predetermined part of the output period that outputs the signal from the terminal. The circuit causes the one transistor and the other transistor to be turned on and off in complementary fashion depending on the value of the signal to be delivered to the terminal.

In one embodiment of the present invention, each chip includes a circuit that receives a signal to be delivered as output to the terminal, an output control signal that controls the output period for the signal, and the test signal. The circuit causes the first transistor to be turned off, in case the test signal is activated, without dependency on the values of the signal to be delivered to the terminal or on the output control signal. The circuit causes the first transistor to be turned on if, with the test signal in inactivated state, the signal is of a first logic value and the output control signal is activated. Each chip also includes another circuit that receives the signal to be delivered to the terminal and the output control signal. The other circuit causes the second transistor to be turned on in case the signal to be delivered to the terminal is of a second logic value and the output control signal is activated. The other circuit causes the second transistor to be turned off otherwise.

In one embodiment of the present invention, there is provided a semiconductor device further comprising a circuit that forces the predetermined one of the first and second output transistors off only during a part of the output period during which the output control signal is activated. The circuit forces the other output transistor on.

In one embodiment of the present invention, each chip includes a first control circuit that generates a one-shot pulse. The one-shot pulse is generated based on an input command signal to prescribe the signal readout timing when the test signal is in activated state. The one-shot pulse is in inactivated state in case the test signal is in inactivated state. Each chip also includes a second control circuit that receives the signal to be delivered to the terminal, the output control signal controlling the outputting of the signal to be delivered to the terminal, the test signal, and the one-shot signal. When the test signal is in inactivated state, the second control circuit causes the first transistor to be turned on during the outputting period when the signal is of a first logic value and the output control signal is activated. The second control circuit causes the first transistor to be turned off when the signal is of a second logic value or the output control signal is inactivated. When the test signal is in activated state, the second control circuit causes the first transistor to be turned on only during the activated time period of the one-shot signal within the outputting period when the output control signal is in activated state. Each chip further includes a third control circuit that receives the signal to be delivered to the terminal, the output control signal and the one-shot signal. When the signal is of a second logic value, the third control circuit causes the second transistor to be turned on if, during the outputting period with the output control signal in activated state, the one-shot pulse is in inactivated state. When the one-shot pulse is activated during the outputting period, with the output control signal in the activated state, the third control circuit causes the second transistor to be turned off during the period of activation of the one-shot signal, while causing the second transistor to be turned on during the period of inactivation of the one-shot signal. The third control circuit causes the second transistor to be turned off when the signal to be delivered to the terminal is of a first logic value.

In one embodiment of the present invention, there is provided a semiconductor device that may further comprise a circuit that generates the one-shot signal based on a timing control signal generated based on an input command signal, the test signal and a signal delayed from a clock signal.

In one embodiment of the present invention, each chip of the semiconductor device includes a semiconductor memory. A chip select signal out of control signals is separately delivered to each chip. An address signal, a data signal, a clock, a read/write signal and strobe signals of the row address system and the column address system are delivered in common to each chip and read data from the chips are output at a common data terminal. The chip select signals of the multiple chips are simultaneously activated during testing to enable the testing.

In one embodiment of the present invention, the signal output to the terminal of each chip during test is in the form of a compressed signal of a plurality predetermined data signals. The signal delivered to the terminal assumes a logic value indicating pass or a logic value indicating fail in case the data signals are all coincident or in case even one or more of the data signals are not coincident, respectively.

In one embodiment of the present invention, the terminals of the multiple chips connected in common may be connected to an external output terminal or an external input and output terminal.

In another embodiment of the present invention, there is provided a semiconductor chip comprising a circuit for driving a terminal that at least outputs a signal towards a first power supply voltage or towards a second power supply voltage, and another circuit that provides a difference between a first driving capability and a second driving capability, responsive to a test signal. The first driving capability drives a terminal to the first power supply voltage and the second driving capability drives the terminal to the second power supply voltage.

In one embodiment of the present invention, there is provided a semiconductor chip comprising a first output transistor that drives a terminal, at least outputting a signal, towards a first power supply voltage, a second output transistor that drives the terminal towards a second power supply voltage, and a circuit that causes a predetermined one of the first and second output transistors to be turned off, at the time of testing, responsive to a test signal.

In one embodiment of the present invention, one of the first and second output transistors may be turned off and the other output transistor may be turned on during a predetermined part of an output period outputting the signal from the terminal during testing. During the other part of output period, the one transistor and the other transistor may be turned on and off in complementary fashion depending on the value of the signal to be delivered to the terminal.

In another embodiment of the present invention, there is provided a method for testing a semiconductor device including a plurality of chips each configured to drive a terminal for outputting a signal, to a first power supply voltage or a second power supply voltage, depending on the value of a signal to be output. The terminals are connected in common and connected together to an external terminal of the semiconductor device. The method comprises setting one of the first driving capability and the second driving capability in each chip so as to be larger than the other, and setting the magnitude correlation between the first driving capability and the second driving capability so as to be common from one chip to another. In the method of the present invention, when at least one of the multiple chips and the remaining chips simultaneously output one and the other of the first and second power supply voltage levels, to the terminals connected in common, respectively, a predetermined one of the first and second power supply voltage levels is output to each terminal depending on the magnitude correlation between the first driving capability and the second driving capability in each chip.

In the method according to another embodiment of the present invention, the second driving capability is set, during testing, so as to be larger than the first driving capability. The signal delivered to the terminal being at the second power supply voltage level indicates fail and the signal delivered to the terminal being at the first power supply voltage level indicates pass. The second power supply voltage is delivered to the external terminal in case even one chip has failed.

In the method for testing a semiconductor device including a plurality of chips, each chip includes a first output transistor that drives a terminal, at least outputting a signal, towards a first power supply voltage, and a second output transistor that drives the terminal towards a second power supply voltage. The terminals are connected in common and connected to an external terminal of the semiconductor device. The method comprises turning off a predetermined one of a circuit that drives the terminal in each chip to the first power supply voltage and a circuit that drives the terminal in each chip to the second power supply voltage in common from one chip to another. When the signal is output from each of terminals connected in common, each terminal assumes one of two states, namely a high impedance state and the voltage level of the first or second power supply.

In the method according to another embodiment of the present invention, the one of the first and second output transistors may be forced off and the other output transistor may be forced on during a predetermined part of an output period outputting the signal from the terminal. The one and the other output transistors may be turned on and off in complementary fashion depending on the value of the signal to be output from the terminal.

In the method according to another embodiment of the present invention, one of the first and second output transistors may be forced off and the other output transistor forced on during a predetermined part of an output period outputting the signal from the terminal during test. The one transistor and the other transistor may be turned on and off in complementary fashion depending on the value of the signal to be output to the terminal.

In the method according to another embodiment of the present invention, the signal delivered to the terminal of each chip at the time of testing may be given as a compressed signal of predetermined multiple data signals. The signal may assume a logic value indicating pass in case of coincidence of all of the multiple data signals and a logic value indicating fail in case of non-coincidence of all of the multiple data signals.

According to the present invention, if, in case a plurality of chips are in selected states simultaneously, and internal data are read out simultaneously from these chips, failed chips are contained in even one of the multiple chips, it is possible to make a fail/pass decision.

Still other features and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1A and FIG. 1B are diagrams showing the configuration of Example 1 of the present invention.

FIG. 2 is a circuit diagram showing the configuration of a data input and output section of FIG. 1.

FIG. 3 is a timing diagram for illustrating an operation of Example 1 of the present invention.

FIG. 4 is a circuit diagram showing the configuration of Example 2 of the present invention.

FIG. 5 is a timing diagram for illustrating an operation of Example 2 of the present invention.

FIG. 6 is a diagram showing the configuration of Example 3 of the present invention.

FIG. 7A and FIG. 7B are diagrams showing the configuration of a data output control section of FIG. 6.

FIG. 8 is a circuit diagram showing the configuration of a data input and output section of FIG. 6.

FIG. 9 is a timing diagram for illustrating an operation of Example 3 of the present invention.

FIG. 10 is a diagram showing the configuration of Example 4 of the present invention.

FIG. 11 is a timing diagram for illustrating a related art technique.

FIG. 12 is another timing diagram for illustrating a related art technique.

### PREFERRED MODES OF THE INVENTION

The present invention will now be described with reference to drawings. In the semiconductor device according to the present invention, there are provided a plurality of chips (11a and 11b) each including a terminal (DQ1, DQ2) that is at least for outputting a signal, to a first power supply voltage (VDD) or to a second power supply voltage (GND), depending on the value of the signal. Each chip (11a and 11b) includes a data input and output circuit (12a, 12b) for providing a difference between a first driving capability driving the terminal (DQ1, DQ2) to the first power supply voltage and a second driving capability driving the terminal to the second power supply voltage at the time of testing.

According to the present invention, if, during testing, at least one of the chips (11a and 11b) delivers a signal at one of a voltage level of the first power supply voltage and a voltage level of the second power supply voltage to the terminals (DQ1, DQ2) connected in common, and the remaining chips deliver output signals at a voltage level of the other of the first and second power supply voltages to the remaining ones of the terminals (DQ1, DQ2), connected in common, at the same time as the one chip delivers the output signal, a preset one of the first and second power supply voltage levels is output in dependence upon the difference as set between the first driving capability and the second driving capability. For example, the first and second chips (11a and 11b) are set in common, during test testing, so that the second driving capability that drives the terminals (DQ1, DQ2) to the second power supply voltage, such as (GND), is higher than the first driving capability that drives the terminals (DQ1, DQ2) to the first power supply voltage, such as (VDD). In case one of the first and second chips (11a and 11b) delivers a signal at the first power supply voltage level to the terminals connected in common and the other of the first and second chips delivers a signal at the second power supply voltage level to the terminals (DQ1, DQ2) connected in common, at the same time as the one chip delivers the output signal, the voltage level of the second power supply voltage (GND level) is output at the external terminal.

In the present invention, a test mode of performing IO compression or even/odd address compression is provided in each chip (11a and 11b). The signals output at the time of testing from the multiple chips (11a and 11b) to the terminals connected in common (DQ1, DQ2) are afforded as compression signals compressed from multiple data signals, and assume a logic value indicating a pass as a decision signal in case all of the multiple data coincide, while assuming a logic value indicating a fail as a decision signal in case even one of the multiple data does not coincide.

In the present invention, the signal level of the signal delivered to the terminals (DQ1, DQ2) connected in common being e.g. the level of the second power supply (GND) indicates a fail and the signal level of the signal delivered to the terminals (DQ1, DQ2) connected in common being e.g. the level of the first power supply (VDD) indicates a pass. Under this condition, the second driving capability is selected to be higher than the first driving capability. If the result of decision for even one of the multiple chips (11a and 11b) is a fail, the second power supply voltage level, that is, a fail signal, is output to the terminals (DQ1, DQ2) connected in common.

A semiconductor device according to the present invention may include a driver strength function of variably setting the first driving capability of driving the terminals (DQ1, DQ2) to the first power supply voltage and the second driving capability of driving the external terminal to the second power supply voltage, based on an input command. During testing, the first driving capability of driving the terminal to the first power supply voltage may be set at a predetermined first value, and the second driving capability of driving the terminal to the second power supply voltage may be set at a predetermined second value different from the first value, responsive to a test signal activated at the time of the testing, by taking advantage of the driver strength function.

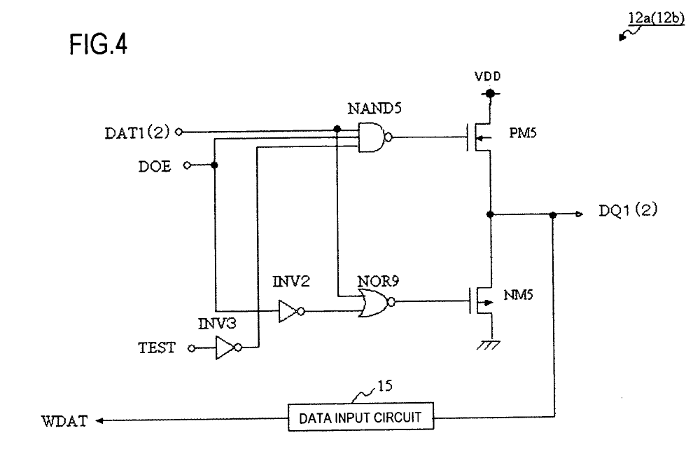

In the present invention, terminals (DQ1, DQ2), of the multiple chips, each at least outputting a signal, are connected in common. Each chip includes a first transistor (PM5 of FIG. 4) that drives the terminals to the first power supply voltage and a second transistor (NM5 of FIG. 4) that drives the terminals to the second power supply voltage. Each chip also includes a circuit (INV3, NAND5) that turns a predetermined one of the first and second output transistors (PM5, NM5) off, at the time of testing, based on the test signal TEST.

According to the present invention, when a signal is output for testing from the terminals (DQ1, DQ2), connected in common, the terminals assume one of two states, namely a high impedance state and one of the first and second power supply voltage levels. According to the present invention, there may be provided a test mode for IO compression or even (EVEN)/odd (ODD) address compression. In reading the result at the time of testing, high impedance may be output in case of data coincidence (for pass), whilst a predetermined logic level, which may be High level (VDD level) and Low level (GND level), may be output in case of non-coincidence (for fail).

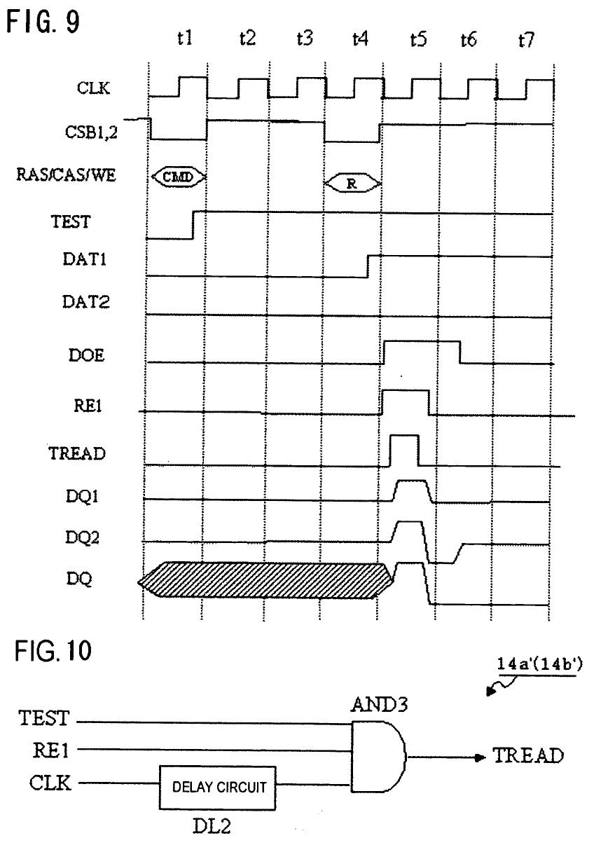

In the present invention, the aforementioned predetermined one (e.g. NM5) of the first and second output transistors (PM5, NM5) driving the terminals (DQ1, DQ2) is forced off during a predetermined partial period (such as High period of a one-shot signal TREAD of FIG. 9) of the data output period outputting data from the terminal, such as the High period of the output enable signal DOE of FIG. 9, with the other output transistor (PM5) being forced on. During a period other than the aforementioned partial period of the data output period, the aforementioned one and the other transistors may be turned on or off, in a complementary fashion, depending on the value of the signal to be delivered to the terminal. The aforementioned predetermined partial period is prescribed by the one-shot signal (TREAD) generated on receipt of a read command.

In the present invention, the aforementioned one-shot signal (TREAD) may be generated based on the aforementioned timing control signal (RE1), generated based on an input command signal (e.g. read command), the aforementioned test signal (TEST) and a delayed version of a clock signal (CLK). With this configuration, one of the first and second transistors driving the terminal is turned on when the read command, for example, is entered and the clock signal rises, and a decision signal is output with falling of the clock signal. The present invention is now described in accordance with specified Examples.

### EXAMPLE 1

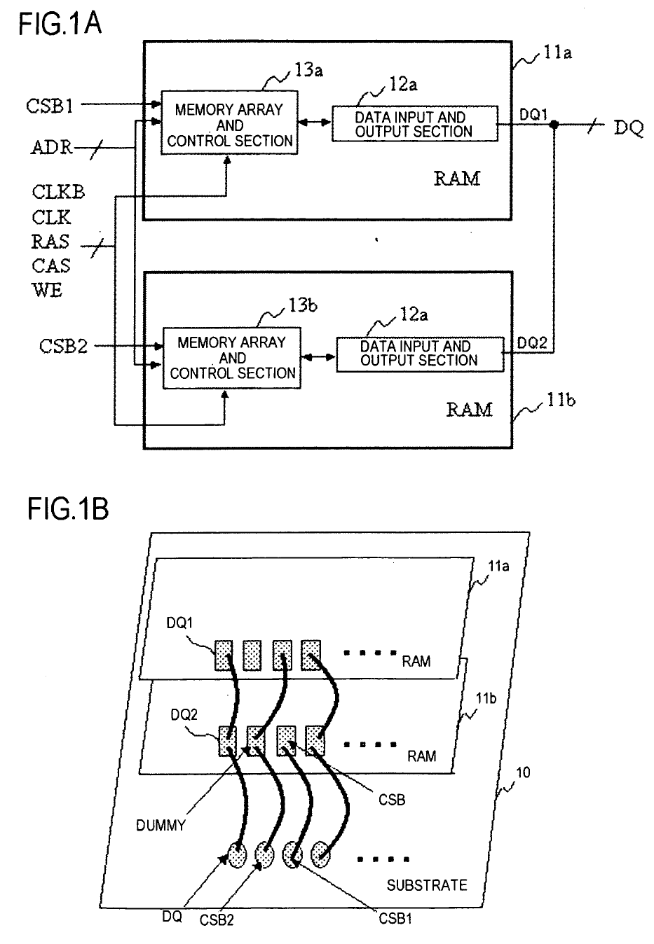

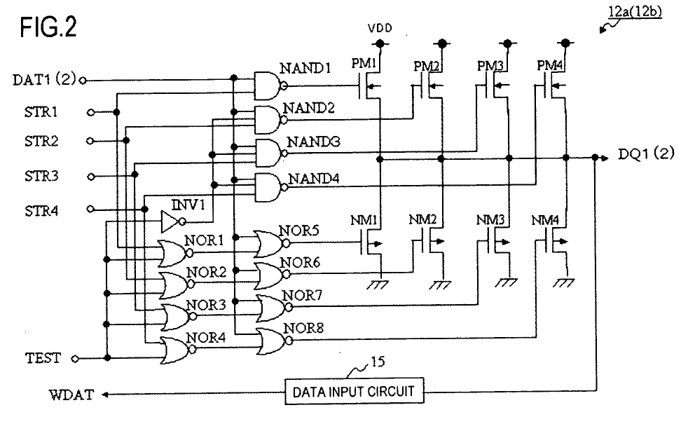

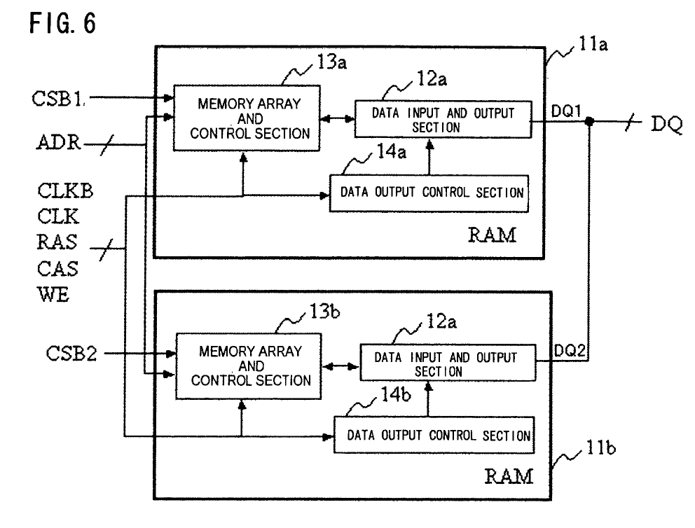

FIG. 1A shows a circuit arrangement of an MCP (Multi-Chip Package) semiconductor memory according to a first exemplary embodiment of the present invention. Referring to FIG. 1A, RAMs (chips) 11a and 11b are formed by synchronous DRAMs of the same configuration. The synchronous DRAMs include a memory array and control section 13a (13b) and a data input and output section 12a (12b). It should be noted that, although an MCP semiconductor memory, including two chips 11a and 11b, is taken up for illustration in the Example 1, shown in FIG. 1 and in Examples of FIGS. 2 and 6, as later described, the number of chips different from two may, of course, be mounted on the MCP semiconductor memory according to the present invention.

Referring to FIG. 1A, the memory array and control section 13a (13b) include a set of well-known components, herein not shown. These components include, for example, a DRAM memory array, a row decoder, a sense amplifier, a column decoder, a clock generator, a command decoder, a mode register, a row address buffer, a refresh counter, a column address buffer, a burst counter, a data control logic section, a data latch section and a DLL (Delay Lock Loop). The data latch section receives write data from the data input and output section 12a (12b), during the write operation, while supplying read data from the sense amplifier to the data input and output section 12a (12b) during the readout operation. The data latch section also delivers data, read out from the sense amplifier and compressed by a coincidence detection circuit, to the data input and output section 12a (12b) during the test operation. The data input and output section 12a (12b) includes an input circuit that receives data from an IO terminal DQ1 (DQ2) during the write operation, and an output circuit that outputs data to the IO terminal DQ1 (DQ2) during the readout operation. The input circuit and the output circuit are omitted from the drawing.

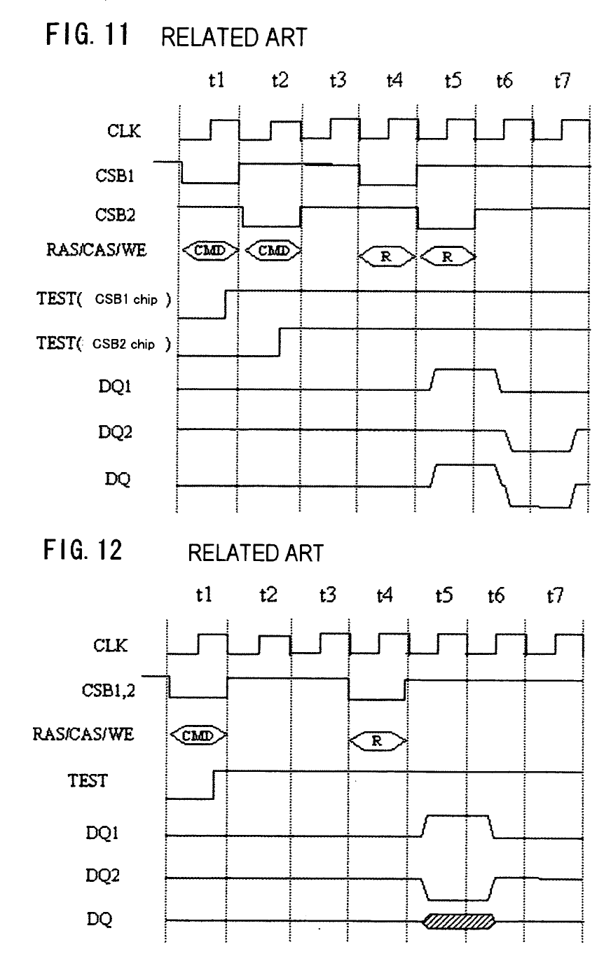

FIG. 1B is a schematic view showing the connection states of two chips mounted on the multi-chip package. Referring to FIG. 1B, the RAMs 11a and 11b are mounted on a substrate 10, and receive various signals via common bonding wires from the substrate 10. Respective chip select signal lines CBS1 and CBS2 for the RAMs 11a and 11b are separately connected via separate bonding wires to the substrate 10. That is, a conductor for the chip select signal CSB2 of the RAM 11a is connected via a dummy pad of the RAM 11b to a pad of the signal line CSB2 of the RAM 11a. By this arrangement, it is possible to supply activated chip select signals CSB1 and CSB2 at different timings (clock cycles) to the RAMs 11a and 11b, as shown in FIG. 11, to have the RAMs perform distinct operations, such as a command inputting operation. On the other hand, a common test signal is delivered from a tester (ATE), not shown, to each of the chip select signal lines CSB1, CSB2 of the RAMs 11a and 11b.

Referring to FIG. 1A, the memory array and control section 13a (13b) receives complementary clock signals CLK and CLKB, a row address strobe (RAS), a column address strobe (CAS) and a write enable (WE), as command input signals, and an address signal ADR, in common, while separately receiving the chip select signal CSB1 and the chip select signal CSB2. A data input and output terminal DQ1 of the RAM 11a and a data input and output terminal DQ2 of the RAM 11b are connected in common to a terminal DQ.

When the RAMs 11a and 11b are in the write mode, the contents of a data signal DQ are stored in a location of the memory array corresponding to the address signal ADR.

When the RAMs 11a and 11b are in the readout mode, the data stored in the location of the memory array corresponding to the address signal ADR is output via the data input and output section 12a (12b) as the data signal DQ.

By selecting and using a test mode of compressing data based on address combinations by a mode register set command operation, a plurality of DQ data and data such as bank addresses are simultaneously selected and read out. These multiple data are checked as to possible coincidence by a coincidence detection circuit, as described above, so that a sole decision result data is output in place of the multiple data. The mode register set command operation for test mode selection is well-known in e.g. an SDRAM and hence the detailed description therefor is dispensed with.

FIG. 2 is a circuit diagram showing the circuit arrangement of the data input and output section 12a or 12b. The data input and output section 12a (12b) is of the same circuit configuration. The connection terminals are labeled DQ1 and DQ2 and read data signals are labeled DAT1 and DAT2.

Referring to FIG. 2, the data input and output section 12a (12b) includes an inverter circuit INV1, a two-input NAND circuit NAND1, three-input NAND circuits NAND2, NAND3 and NAND4. The data input and output section also includes two-input NOR circuits NOR1 to NOR8, four P-channel MOS transistors PM1 to PM4 with respective different channel widths, and N-channel MOS transistors NM1 to NM4 with respective different channel widths. The data input and output section further includes a data input circuit 15.

The two-input NAND circuit NAND1 receives the read data signal DAT1 (DAT2), and a driver strength signal STR1.

The three-input NAND circuit NAND2 receives the read data signal DAT1, a driver strength signal STR2, and an output signal of the inverter circuit INV1 that receives the test signal TEST. This output signal is an inverted version of the test signal TEST.

The three-input NAND circuit NAND3 receives the read signal DAT1, a driver strength signal STR3, and an output signal of the inverter circuit INV1. This output signal is inverted version of the test signal TEST.

The three-input NAND circuit NAND4 receives the read signal DAT1, a driver strength signal STR4, and an output signal of the inverter circuit INV1. This output signal is inversion of the test signal TEST.

The two-input NOR1 receives the driver strength signal STR1 and the test signal TEST.

The two-input NOR2 receives the driver strength signal STR2 and the test signal TEST.

The two-input NOR3 receives the driver strength signal STR3 and the test signal TEST.

The two-input NOR4 receives the driver strength signal STR4 and the test signal TEST.

The two-input NOR5 receives the read data signal DAT1 and an output signal of NOR1.

The two-input NOR6 receives the read data signal DAT1 and an output signal of NOR2.

The two-input NOR7 receives the read data signal DAT1 and an output signal of NOR3.

The two-input NOR8 receives the read data signal DAT1 and an output signal of NOR4.

The P-channel MOS transistors PM1 to PM4 have source terminals connected in common to a power supply, have drain terminals connected in common to the input and output terminal DQ1 (DQ2 if the chip is the chip 11b) and have gate terminals connected to output terminals of the NAND circuits NAND1 to NAND4.

The N-channel MOS transistors NM1 to NM4 have source terminals connected in common to the ground potential, have drain terminals connected in common to the input and output terminal DQ1 and have gate terminals connected to output terminals of the NOR circuits NOR5 to NOR8.

Since DQ1 is an input and output terminal (IO terminal), it is connected to an input of the data input circuit 15, which data input circuit 15 delivers a write data signal WDAT as output.

It should be noted that, in FIG. 2, the driver strength is the ability of varying the current driving capability of the output driver, and is used in e.g. a mobile RAM. The driver's capability is set by the mode register command in keeping with various changes in the environment of the input and output transmission lines.

In the mobile RAM, the number of the first to fourth driver strength signals STR1 to STR4 that should be made High is varied in keeping with the mode as set by the mode register command.

By so doing, the number of the output transistors that are to be turned on may be selected to change the driving capability (charging driving capability and discharging driving capability) of the output transistors. The operation of the driver strength command is well-known in e.g. a mobile RAM and hence the detailed description thereof is dispensed with.

Referring to FIG. 2, during the normal operation, TEST is set to Low, and the output of the inverter circuit INV1 is set to High. When DAT1 is High, those out of the P-channel MOS transistors PM1 to PM4 associated with Highs of the first to fourth driver strength signals STR1 to STR4 are turned on to charge the terminal DQ1. When DAT1 is Low, the N-channel MOS transistors associated with Highs of the first to fourth driver strength signals STR1 to STR4 are turned on to discharge the terminal DQ1.

During the normal operation, TEST is set to Low, and all of the first to fourth driver strength signals STR1 to STR4 are set to High. When DAT1 is High, the output signals of NAND1 to NAND4 are all Low, and hence the P-channel MOS transistors PM1 to PM4 are turned on. When DAT1 is High, output signals of NOR5 to NOR8 are all Low, so that the N-channel MOS transistors NM1 to NM4 are all turned off.

In case the first to fourth driver strength signals STR1 to STR4 are all set to High, the output signals of NOR1 to NOR 4 are all Low. If DAT1 is Low, the output signals of NOR 5 to NOR 8 are all High. Thus, the N-channel MOS transistors NM1 to NM4 are all turned on. The output signals of NAND1 to NAND4, on the other hand, are all brought High, so that the P-channel MOS transistors PM1 to PM4 are turned off. That is, with DAT1 High, the four P-channel MOS transistors PM1 to PM4 operate simultaneously for charging the terminal DQ1 (DQ2), and with DAT1 Low, the four N-channel MOS transistors NM1 to NM4 operate simultaneously for discharging the terminal DQ1(2).

A case will now be described in which during the normal operation, (TEST=Low), the first and second driver strength signals STR1 and STR2 are set to High, and the third and fourth driver strength signals STR3 and STR4 are set to Low. When DAT1 is High in this case, outputs of NAND1 and NAND2 are Low, while those of NAND3 and NAND4 are High. Thus, the P-channel MOS transistors PM1 and PM2 are turned on, while the P-channel MOS transistors PM3 and PM4 are turned off. Outputs of NOR 5 to NOR 8 are all brought Low, thus turning off the N-channel MOS transistors NM1 to NM4. When DAT1 is Low, outputs of NOR1 and NOR 2 are brought Low, while those of NOR 3 and NOR 4 are brought High. Outputs of NOR 5, NOR 6 are brought High, while those of NOR 7 and NOR 8 are brought Low. Outputs of the N-channel MOS transistors NM1, NM2 are turned on, while those of the N-channel MOS transistors NM3, NM4 are turned off. Outputs of NAND1 to NAND4 are all brought High to turn off the P-channel MOS transistors PM1 to PM4. That is, with DAT1 High, the two N-channel MOS transistors NM1 and NM2, associated with the driver strength signals STR1 and STR2, which are then High, operate simultaneously for charging the terminal DQ1(2), whereas, with DAT1 Low, the two N-channel MOS transistors NM1, NM2, associated with the driver strength signals STR1 and STR2, which are then High, operate simultaneously for discharging the terminal DQ1(2). The same applies for other selections of the first to fourth driver strength signals STR1 to STR4.

In the test mode (TEST=High), since priority is placed on the results of detection of a failed chip or chips, outputs of NAND2 to NAND4 are brought High, without dependency on STR2 to STR4 or on read data DAT1, thereby turning off the P-channel MOS transistors PM2 to PM4. With STR1 High, when DAT1 is High, an output of NAND1 is brought Low to turn on the P-channel MOS transistor PM1. When DAT1 is Low, an output of NAND1 is brought High to turn off the P-channel MOS transistor PM1. Since TEST is High, output signals of NOR1 to NOR 4 are brought Low, without dependency on STR2 to STR4. With DAT1 Low, NOR 5 to NOR 8 output High to turn on the N-channel MOS transistors NM1 to NM4. With DAT1 High, NOR 5 to NOR 8 output Low to turn off the N-channel MOS transistors NM1 to NM4.

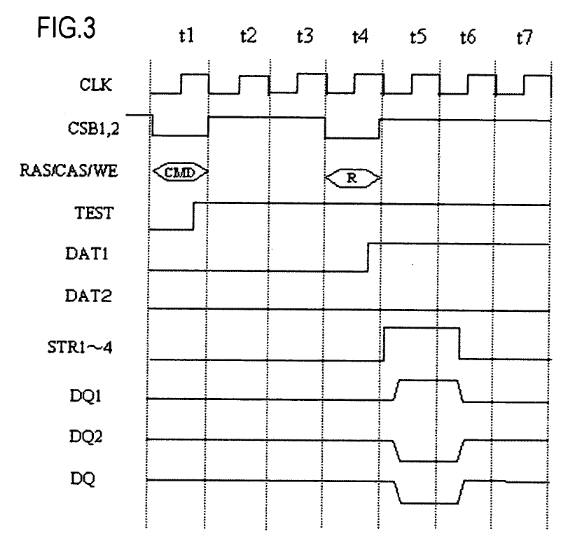

Referring to the timing chart of FIG. 3, the operation of the MCP semiconductor memory of the present Example is now described.

At timing t1, a mode register set command for selecting the test mode for performing data compression is entered. At timing t4, a read command is entered.

At timing t1, the test mode for data compression is set, so that the test signal TEST is brought High. In the test mode for data compression, read data from multiple data lines of the memory cells are entered to the coincidence detection circuit. In case of coincidence of the multiple read data, the coincidence detection circuit outputs a High. If even one of the read data is non-coincident, the coincidence detection circuit outputs a Low. An exclusive NOR (EXNOR) circuit is used as the coincidence detection circuit.

Then, at timing t4, a compressed data signal DAT1 (EXNOR logic result signal of data being compressed) is output from the memory array and control section 13a (13b). Since all data of DAT1 on the chip 11a are coincident to the written data, a High is output as being the result of EXNOR logic. On the chip 11b, there is a failed bit or bits in the written bits, so that the result indicates non-coincidence. Hence, a Low is output as the signal DAT2.

At timing t1, the test signal TEST is High, so that the output of the inverter INV1 is brought Low. Hence, the outputs of the NAND2, NAND3 and NAND4 are all high, whilst outputs of NOR1 to NOR4 are all Low.

On the chip 11a, an output of NAND1, receiving a High of the read data signal DAT1 and a High of STR1, is brought Low to turn on the P-channel MOS transistor PM1. Also, on the chip 11a, outputs of NOR5 to NOR8 that receive a High of the read data signal DAT1 are all brought Low to turn off the N-channel MOS transistors NM1 to NM4. The output terminal DQ1 of the data input and output section of the chip 11a is brought High with the P-channel MOS transistor PM1 in an on-state.

On the chip 11b, outputs of NAND1 to NAND4, receiving the Low of the read data signal DAT2, are all High to turn off the P-channel MOS transistors PM1 to PM4. On the chip 11b, outputs of NOR5 to NOR8, receiving the Low of the read data signal DAT2 and the Lows of NOR1 to NOR4, are brought High, so that the N-channel MOS transistors NM1 to NM4 are all turned on. That is, the output terminal DQ2 of the data input and output section on the chip 11b is brought Low with the N-channel MOS transistors NM1 to NM4 all being in an on-state.

On the chip 11a, the sole P-channel MOS transistor PM1 charges the terminal DQ. On the chip 11b, affording a failed output, the N-channel MOS transistors NM1 to NM4 discharge the terminal DQ. Since the current driving capability for charging the chip 11b, delivering a failed output, is higher than the current driving capability of the transistor for charging the chip 11a, the terminal DQ delivers Low as its output. With the equal current driving capability of the P-channel MOS transistor and the N-channel MOS transistor, the ratio of the charging driving capability for the terminal DQ to the discharging driving capability for the same terminal DQ is 1:4. Supposing that there are three chips, the terminals of which are connected in common to the IO terminal DQ, with the read data (result of decision) of two chips being High and with the read data (result of decision) of the remaining chip being Low, the ratio of the charging driving capability and the discharging driving capability for the terminal DQ is 2:4. It is thus possible to set the potential at the terminal DQ to Low.

In the configuration shown in FIG. 2, four PMOS transistors are connected in parallel between the terminal DQ1 (DQ2) and the power supply VDD, while four NMOS transistors are connected in parallel between the terminal DQ1 (DQ2) and GND. Of course, the present invention is not limited to this configuration. For example, if the number of the multiple chips is increased further, the number of the PMOS transistors, connected in parallel between the terminal DQ1 (DQ2) and the power supply VDD, and that of the NMOS transistors, connected between the terminal DQ1 (DQ2) and GND, may correspondingly be increased.

With the present exemplary embodiment, if, in case multiple chips provided on the semiconductor memory are simultaneously selected and the results of the internal data are read simultaneously, there is even one failed chip among the multiple chips, it is possible to give a pass/fail decision. It is because the driving capability of the N-channel transistors on the failed chip is high such that the output terminal DQ is brought Low.

### EXAMPLE 2

An Example 2 of the present invention will now be described with reference to the drawings. FIG. 4 depicts a circuit diagram showing a data input and output section 12a (12b) of the MCP semiconductor memory of the Example 2 of the present invention. It should be noted that the above-described Example 1 is directed to an MCP semiconductor memory having the drive strength function. In the Example 2, the present invention is applied to a configuration not having the drive strength function.

Referring to FIG. 4, the data input and output section 12a (12b) includes inverter circuits INV2, INV3, a NAND circuit NAND5, a NOR circuit NOR9, a P-channel MOS transistor PM5, an N-channel MOS transistor NM5 and a data input circuit 15.

The inverter circuit INV2 receives an output enable signal DOE to output its inverted signal. The output enable signal DOE is an output control signal. During the normal operation, the time period the signal DOE is High represents an output time period for the read data.

The inverter circuit INV3 receives the test signal TEST to output its inverted signal.

The three-input NAND circuit NAND5 receives a read data signal DAT1 (DAT2 if the chip is the chip 11b), the output enable signal DOE and an output signal of the inverter circuit INV3 (inverted version of TEST).

The two-input NOR circuit NOR 9 receives a read data signal DAT1 (DAT2 if the chip is the chip 11b), and an output signal of the inverter circuit INV2 (inverted version of DOE).

The PMOS transistor PM5 has a source terminal connected to a power supply, has a drain terminal connected to an input and output terminal DQ1 (DQ2 if the chip is the chip 11b) and has a gate terminal connected to an output of the NAND circuit NAND5.

The N-channel MOS transistor NM5 has a source terminal connected to a ground potential, has a drain terminal connected to the input and output terminal DQ1 and has a gate terminal connected to an output of the NOR circuit NOR9.

Meanwhile, since DQ1 is an input and output terminal, it is connected to the data input circuit 15, as in the Example 1, and outputs a write data signal WDAT.

During the test mode, TEST becomes High, so that the output signal of the inverter INV3 is brought Low, and hence the output signal of NAND5 is brought High. That is, the output of NAND5 is set to High, without regard to the read data signal DAT1 or the output enable signal DOE, thereby turning off the PMOS transistor PM5.

When DAT1 High (pass), the output of NOR 9 becomes Low to turn off the N-channel MOS transistor NM5. Since the P-channel MOS transistor PM5 is off, the IO terminal DQ1 is in a high impedance state.

When DAT1 is Low (fail), the output of NOR 9 becomes High, in response to High of DOE, to turn on the transistor NM5 to set the IO terminal DQ1 to Low.

Thus, when the read data signal DAT1 is High, in the RAM 1a, during testing, DQ1 is in a high impedance state. When the read data signal DAT1 is Low, DQ1 is at Low level. In similar manner, in the RAM 1b, when the read data signal DAT2 is High or Low, DQ2 is in a high impedance state or at a Low level, respectively. That is, during the read operation for test, the external terminal DQ, to which DQ1 of RAM 1a and DQ2 of RAM 1b are connected in common, assumes two values, namely a high impedance state and Low.

During the normal operation (TEST=Low), an output of the inverter INV3 becomes High. When the read data signal DAT1 (DAT2) and the output enable signal DOE are both High, NAND5 becomes Low to turn on the P-channel MOS transistor PM5 to set DQ1 (DQ2) to High level. An output of the inverter INV2 goes Low, during the High period of the signal DOE, in case DAT1 (DAT2) is Low. When DAT1 (DAT2) Low, during DOE being High, the output of the inverter INV2 is Low, and hence the output of NOR 9 goes High. This turns on the N-channel MOS transistor NM5 to set the terminal DQ1 (DQ2) to Low level.

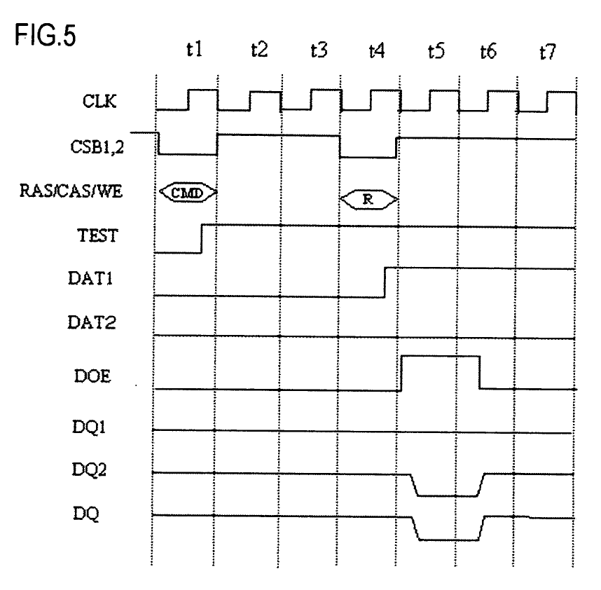

Referring to the timing chart of FIG. 5, the operation of the MCP semiconductor memory of the present Example is now described.

At timing t1, a mode register set command for selecting the test mode for data compression is entered, as in Example 1, described above. At timing t4, a read command is entered.

Initially, at timing t1, the test mode for data compression is set, and the test signal TEST is brought High.

Then, at timing t4, a compressed data signal DAT1 (EXOR logic result signal of data for compression) is output from the memory array and control section. However, DAT1 on the chip 11a is free of failed bits and hence the as-written data is output. Thus, the result of the EXNOR logic is High. On the chip 11b, there is a failed bit or bits, among the as-written bits, so that the result of coincidence detection indicates non-coincidence. Hence, a Low is output as DAT2 signal.

The present Example differs from the above Example 1 in the following respect: That is, the test signal TEST is delivered only to the NAND circuit NAND5 that controls the P-channel MOS transistor. Hence, even though the output enable signal DOE is High, the transistor PM5 on the chip 11a is not turned on. The N-channel MOS transistor NM5 also is in an off-state. The result is that the output DQ1 is in a high impedance state.

As regards the output terminal DQ2 of the data input and output section 12b on the chip 11b, the N-channel MOS transistor NM5 is turned on at the same time as the output enable signal DOE goes High. Thus, the output DQ2 goes Low, so that, if there is one or more failed chips, the output DQ of the MCP semiconductor memory goes Low to enable a pass/fail decision.

In the present Example, if the multiple chips, having data input and output terminals connected in common to the terminal DQ, are all free of a failed bit or bits during the testing, only a high impedance (Hi-z) is output. Hence, a load device (termination resistor element) that may be used to give a decision on the high-impedance state, indicating non-fail, needs to be connected to the terminal DQ. For example, the terminal DQ may be connected to a load on a test board of the tester (ATE). This load may, for example, be a dynamic load having the load varied depending on the output state. The high impedance Hi-z may be detected by a comparator (window comparator) connected to the terminal DQ in turn connected to the load.

### EXAMPLE 3

An Example 3 of the present invention will now be described with reference to the drawings. FIG. 6 depicts the configuration of an MCP semiconductor memory according to Example 3 of the present invention. In the present Example, a data output control section 14a (14b) is further provided in addition to the data input and output section 12a (12b) of Example 1 shown in FIG. 1.

In the above Example 2, it is necessary to provide a device that verifies the high impedance state, indicating the immunity from fail, such as a termination resistor element. With the present Example, such device may be dispensed with.

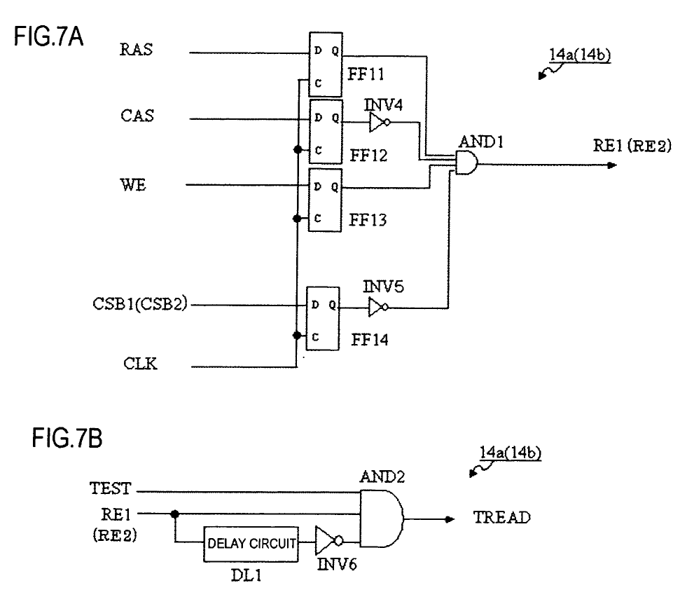

FIGS. 7A and 7B depict circuit diagrams showing a circuit arrangement of the data output control section 14a (14b). Referring to FIG. 7A, the data output control section 14a (14b) includes D-type flip-flop circuits FF11 to FF14, inverter circuits INV1, INV2 and a four-input AND circuit AND1. The inverter circuits are equivalent to register circuits.

A clock signal CLK is delivered to respective clock terminals of the D-type flip-flop circuits FF11 to FF14. In addition, a row address strobe (RAS), a column address strobe (CAS), a write enable (WE), and a chip select signal CSB1 (CSB2), are delivered as command input signals to data input terminals (D-terminals) of the D-type flip-flop circuits. The D-type flip-flop circuits FF11 to FF14 sample signals at the data input terminal D, with a rising edge of the clock CLK, to output sampled data at a data output terminal Q. Hence, the D-type flip-flop circuits FF11 to FF14 are each equivalent to an edge-triggered register.

The four input terminals of the four-input AND circuit AND1 are connected to a data output terminal Q of the D-type flip-flop circuit FF11, an output terminal of the inverter circuit INV1, a data output terminal Q of the D-type flip-flop circuit FF13, and to an output terminal of the inverter circuit INV2. The inverter circuit INV1 has an input connected to the data output terminal Q of the D-type flip-flop circuit FF12, and the inverter circuit INV2 has an input connected to the data output terminal Q of the D-type flip-flop circuit FF14. AND1 outputs a read command decision signal RE1 (RE2) that goes High in case a sampled value of RAS is High, inverted version of the sampled value of CAS is High, a sampled value of WE is High and inverted version of the sampled value of CSB1 (CSB2) is High, that is, in case a read command is delivered as input.

Referring to FIG. 7B, the data output control section 14a (14b) further includes a delay circuit DL1, an inverter circuit INV6 and an AND circuit AND6. When TEST is High, the AND circuit AND2 receives a high pulse of RE1 to set its output to High and outputs a High pulse as TREAD (test read). This High pulse TREAD has a pulse width equal to the delay caused by the delay circuit DL1

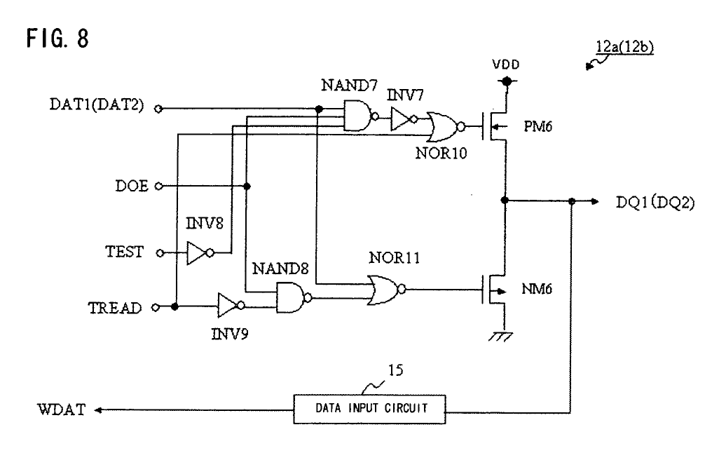

FIG. 8 depicts a circuit diagram showing an arrangement of the data input and output section 12a (12b) of an MCP semiconductor memory of Example 3 of the present invention. Referring to FIG. 8, the present Example includes an inverter INV8 that receives the test signal TEST, a three-input NAND circuit NAND7 that receives DAT1 (DAT2), an output enable signal DOE, and an output signal of the inverter INV8, an inverter INV7 that receives an output of NAND7, and a two-input NOR circuit NOR10 that receives an output signal of the inverter INV7 and TREAD. The present Example also includes an inverter INV9 that receives TREAD, an inverter INV9 that receives the signal TREAD, a two-input NAND circuit NAND8 that receives the signal DOE and an output of the inverter INV9, and a two-input NOR circuit NOR11 that receives DAT1 and an output of the two-input NAND circuit NAND8. The present Example further includes a P-channel MOS transistor PM6, having a source connected to the power supply VDD, having a drain connected to the terminal DQ1 and having a gate connected to an output of NOR10, and an N-channel MOS transistor NM6, having a source connected to the ground, having a drain connected to the terminal DQ1 and having a gate connected to an output of NOR11, respectively. The output enable signal DOE is generated by the data output control section 14a (14b) so as to be delivered to the data input and output section 12a (12b), only by way of illustration. The output enable signal DOE may also be supplied from outside by a memory controller or a processor to the RAM chips 11a and 11b.

During the normal operation (TEST=Low), when DAT1 (DAT2) is High and DOE is High, an output of NAND7 is brought Low, while the output of INV7 is brought High and the output of NOR10 is brought Low. The P-channel MOS transistor PM6 is thus turned on to charge DQ1 (DQ2) to the power supply VDD to a High level. On the other hand, when DAT1 (DAT2) is Low or DOE is Low, the output of NAND7 is brought High, while the output of INV7 is brought Low. When the test signal TEST Low, the signal TREAD is fixed at Low, and hence the output of NOR10 is brought High to turn off the P-channel MOS transistor PM6. When DAT1 (DAT2) is Low, DOE is High, and the output of the inverter INV9 is High. The output of NAND8 is thus Low and an output of NOR11 is High to turn on the N-channel MOS transistor NM6. The terminals DQ1 (DQ2) are discharged to GND potential to Low level.

During the test mode (TEST=High), the output of the inverter INV8 is brought Low, so that the output of NAND8 is brought High, regardless of the value of DAT1 (DAT2). Hence, the output of the inverter INV7 goes Low. During the High period of the one-shot signal TREAD (High pulse period), the output of NOR10 goes Low to turn on the P-channel MOS transistor PM6 to charge the terminals DQ1 (DQ2) to the power supply potential VDD. When TREAD is Low, the output of NOR10 goes High to turn off the P-channel MOS transistor PM6. In case DAT1 (DAT2) is Low, when DOE is High (outputting period) and TREAD is Low, the output of NAND8 goes Low and the output of NOR11 goes High to turn on the N-channel MOS transistor NM6 to discharge DQ1 (DQ2) to GND potential. When TREAD is High, the output of INV9 goes Low and the output of NAND8 goes High, so that the output of NOR11 goes Low to turn off the N-channel MOS transistor NM6. During the test mode, when DAT1 (DAT2) is High, the output of NOR11 goes Low to turn off the N-channel MOS transistor NM6.

FIG. 9 depicts a timing diagram for illustrating the operation of the Example 3 of the present invention. The timing diagram indicates that a mode register set command for selecting the test mode for data compression and a read command are entered at t1 and t4, respectively, as in the Examples 1 and 2 described above. In FIG. 9, the read command decision signal RE1 and the test read signal (TREAD), generated by the data output control section 14a (14b), are shown in addition to the signals for the Example 2 shown in FIG. 5.

The read command decision signal RE1 (RE2), output from the AND circuit AND1 of the data output control section 14a (14b) of FIG. 7A, goes High, indicating the read state, in synchronization with falling of the clock signal CLK, when the command input signals RAS, CAS and WE and the chip select signal CSB1 (CSB2) are brought High, Low, High and Low at timing t4, respectively.

With the signal RE1 High, the output of the AND circuit AND2 that receives the test signal TEST goes High. After time delay by the delay circuit DL1 and the inverter INV6, an input from the inverter 6 to the AND circuit AND2 goes Low. The signal TREAD then goes Low.

As a result, the AND circuit AND2 of FIG. 7B outputs, on receipt of a High of the RE1 signal, a High one-shot pulse, as the TREAD signal.

With the Example 2, the P-channel MOS transistor PM5 is off during High of the test signal TEST. Referring to FIG. 8, the operation of the data input and output section is such that the P-channel MOS transistor PM6 is turned on only during the High of TREAD. On the other hand, the N-channel MOS transistor NM6 is turned off by the inverter circuit INV9 and the NAND circuit NAND8.

Thus, the terminal DQ1 on the chip 11a and the terminal DQ2 on the chip 11b are both High.

Subsequently, the terminal DQ1 on the chip 11a is in the high impedance state. If there is a failed or bits on the chip 11b, the terminal DQ2 outputs Low.

If there is no failed bit or bits, both the terminals DQ1 and DQ2 of the chips 11a and 11b are in the high impedance state. This High state is kept in the absence of the termination resistor elements, so that it becomes possible to give a pass or fail decision even in the absence of the termination resistor element.

### EXAMPLE 4

FIG. 10 shows the configuration of an Example 4 of the present invention. The data output control section 14a (14b) of FIG. 7B outputs, as TREAD, a one-shot pulse responsive to a High of the signal RE1. In the present Example, TREAD is generated with use of the clock signal CLK. The clock signal CLK is delivered to the delay circuit DL2, and an AND circuit AND3 takes a logical product of TEST, RE1 and an output of a delay circuit DL2 to output a resultant signal TREAD. The delay time of the delay circuit DL12 is set in keeping with the outputting time of RE1.

In the present Example, the data input and output section is so designed that, with the test signal TEST High, the P-channel MOS transistor PM6 of the data input and output section 12a (12b) of FIG. 8 is turned on only as long as the clock signal CLK remains High as from the timing of generation of the one-shot pulse of the TREAD signal by RE1. That is, the operation of the present Example is basically the same as the Example described above with reference to FIG. 9. Thus, referring to FIG. 9, the signal TREAD, brought High with the rising of RE1, goes Low in synchronization with the falling edge of a clock delayed from the clock signal CLK.

The present invention, described above with reference to the above Examples, may be applied with advantage to an MCP semiconductor system that makes use of a plurality of chips to provide a large capacity DRAM. However, the present invention may be applied in general to a system tested in a state the output terminals (input and output terminals) of the multiple chips are connected together.

The disclosures of the aforementioned Patent Documents 1 to 5 are incorporated by reference herein. The particular exemplary embodiments or examples may be modified or adjusted within the gamut of the entire disclosure of the present invention, inclusive of claims, based on the fundamental technical concept of the invention. Further, variegated combinations or selections of the elements disclosed herein may be made within the framework of the claims. That is, the present invention may encompass various modifications or corrections that may occur to those skilled in the art within the gamut of the entire disclosure of the present invention, inclusive of claim and the technical concept of the present invention.

What is claimed is:

1. A semiconductor device comprising:
a plurality of chips, each of the chips including:
a terminal outputting a signal;
a circuit that drives the terminal to a first power supply voltage or to a second power supply voltage; and
a circuit that, responsive to a test signal, provides a difference between a first driving capability driving the terminal to the first power supply voltage and a second driving capability driving the terminal to the second power supply voltage;
the terminals of the plurality of chips being coupled together and connected to an external terminal of the semiconductor device.

2. The semiconductor device according to claim 1, wherein, in case at least one of the chips delivers a signal at one of a voltage level of the first power supply voltage and a voltage level of the second power supply voltage to the terminals connected in common, and remaining chips deliver signals at the other voltage level to the terminals, connected in common, during testing,
at the same time as the at least one chip delivers the signal, a preset one level out of the first and second power supply voltage levels is output at the external terminal in dependence upon the difference as set between the first driving capability and the second driving capability.

3. The semiconductor device according to claim 1, wherein the plurality of chips include first and second chips, wherein
in the first and second chips, the second driving capability is set, during testing, responsive to the test signal, so as to be higher than the first driving capability, and wherein
in case one of the first and second chips delivers a signal at the first power supply voltage level to the terminals connected in common and the other of the first and second chips delivers a signal at the second power supply voltage level at the terminals connected in common, at the same time as the one chip delivers the output signal, the voltage level of the second power supply voltage is output at the external terminal.

4. The semiconductor device according to claim 1, wherein, responsive to the test signal, the second driving capability is set so as to be higher than the first driving capability, and wherein
under the condition that a signal output in each of the chips to the terminal is a fail signal and a pass signal in case the signal level is that of the second power supply voltage and in case the signal level of the signal is that of the first power supply voltage, respectively, the voltage level of the second power supply voltage is output to the terminals connected in common in case at least one of the chips outputs a fail signal.

5. The semiconductor device according to claim 1, including
a driver strength function circuit that variably sets the first driving capability of driving the terminal to the first power supply voltage and the second driving capability of driving the terminal to the second power supply voltage, based on an input command; and
a control circuit that operates for setting, during testing, responsive to a test signal activated at the time of the testing, by using the driver strength function, the first driving capability of driving the terminal to the first power supply voltage at a predetermined first value and for setting the second driving capability of driving the terminal to the second power supply voltage at a predetermined second value different from the first value.

6. The semiconductor device according to claim 1, wherein
the plurality of chips each include:
a first set of a plurality of (a n-number of) transistors, connected in parallel between terminals providing the first power supply voltage and the terminal;
a second set of a plurality of (a n-number of) transistors, connected in parallel between terminals providing the second power supply voltage and the terminal; and
a control circuit that performs control, during testing, based on the test signal, so that, if a signal supplied to each of the terminals providing the first power supply voltage is of a first logic value, a predetermined i-number of the n-number of the transistors of the first set, where i is not less than 1 and less than n, are turned on, and so that the n-number of the transistors of the second set are turned off,
the control circuit also performing control, during testing, based on the test signal, so that, if a signal supplied to each of the terminals providing the second power supply voltage is of a second logic value, a predetermined j-number of the n-number of the transistors of the second set, where j is larger than i and less than n, are turned on, and so that the n-number of the transistors of the first set are turned off.

7. The semiconductor device according to claim 6, wherein the control circuit includes
a first to an n-th logic circuits, having outputs connected to control terminals of an n-number of the transistors of the first set, respectively; and
a first to an n-th distinct logic circuits, having outputs connected to control terminals of an n-number of the transistors of the second set, respectively;
the first logic circuit operating so that, if, out of first to n-th selection signals that select the driving capability, the first selection signal is activated, the signal to be supplied to each of the terminals providing the first power supply voltage is of a first logic value, a corresponding first one of the n-number of the transistors of the first set is turned on;
the i-th logic circuit, where i is not less than 2 and not more than n, operating so that, if, out of first to n-th selection signals that select the driving capability, the i-th selection signal is activated, the signal to be supplied to each of the terminals is of a first logic value, and the test signal is inactivated, a corresponding i-th transistor out of the n-number of the transistors of the first set are turned on;
the i-th logic circuit operating so that, if the test signal is activated, the corresponding i-th transistor out of the n-number of the transistors of the first set is turned off without dependency on the signal to be supplied to each of the terminals and the i-th selection signal:
the i-th distinct logic circuit, where i is not less than 1 and less than n, operating so that, in case the test signal is activated, a corresponding i-th transistor of the n-number of the transistors of the second set is turned on, without dependency on the values of the signal to be supplied to the terminal and a corresponding i-th selection signal out of the first to n-th selection signals;
the i-th distinct logic circuit operating so that, if, with the test signal in inactivated state, the signal to be supplied to the terminal is of a second logic value and the i-th selection signal is in activated state, a corresponding i-th transistor of the n-number of the transistors of the second set is turned on.

8. A semiconductor device comprising:
a plurality of chips, each of the chips including:
a terminal outputting a signal;
a first output transistor that drives the terminal to a first power supply voltage;
a second output transistor that drives the terminal to a second power supply voltage; and
a circuit that, responsive to a test signal, turns off a predetermined one of the first and second output transistors, during testing;
the terminals of the plurality of chips being coupled together and connected to an external terminal of the semiconductor device.

9. The semiconductor device according to claim 8, wherein, when the signals are output from the terminals, connected in common, each of the terminals assumes one of two states, namely a high impedance state and the voltage level of the first or second power supply.

10. The semiconductor device according to claim 8, wherein each of the chips further comprises:
a circuit that turns off said predetermined one of the first and second output transistors during a predetermined part of an output period that outputs the signal from the terminal.

11. The semiconductor device according to claim 8, wherein each of the chips further comprises:
a circuit that forces the one of the first and second output transistors off and forces the other output transistor on during the predetermined part of the output period that outputs the signal from the terminal, the circuit causing the one transistor and the other transistor to be turned on and off in complementary fashion during a period other than the predetermined part of the output period depending on the value of the signal to be delivered to the terminal.

12. The semiconductor device according to claim 8, wherein each of the chips includes
a circuit that receives a signal to be delivered to the terminal, an output control signal that controls the output period for the signal, and the test signal, the circuit causing the first transistor to be turned off, in case the test signal is activated, without dependency on the values of the signal to be delivered to the terminal and the output control signal,
the circuit causing the first transistor to be turned on if, with the test signal in inactivated state, the signal is of a first logic value and the output control signal is activated; and
another circuit that receives the signal to be delivered to the terminal and the output control signal,
the other circuit causing the second transistor to be turned on in case the signal to be delivered to the terminal is of a second logic value and the output control signal is activated,
the other circuit causing the second transistor to be turned off otherwise.

13. The semiconductor device according to claim 12, further comprising:
a circuit that forces the predetermined one of the first and second output transistors off only during a part of the output period during which the output control signal is activated,
the circuit forcing the other output transistor on.

14. The semiconductor device according to claim 10, wherein each of the chips includes
a first control circuit that generates a one-shot pulse, the one-shot pulse being generated based on an input command signal to prescribe a signal readout timing when the test signal is in activated state,
the one-shot pulse being in inactivated state in case the test signal is in inactivated state,
each of the chips also including
a second control circuit receiving the signal to be delivered to the terminal, the output control signal controlling the outputting of the signal to be delivered to the terminal, the test signal and the one-shot signal,
the second control circuit when the test signal is in inactivated state causing the first transistor to be turned on during the outputting period when the signal is of a first logic value and the output control signal is activated,
the second control circuit causing the first transistor to be turned off when the signal is of a second logic value or the output control signal is inactivated,
the second control circuit when the test signal is in activated state causing the first transistor to be turned on only during the activated time period of the one-shot signal within the outputting period when the output control signal is in activated state; and
a third control circuit receiving the signal to be delivered to the terminal, the output control signal and the one-shot signal,
the third control circuit when the signal is of a second logic value causing the second transistor to be turned on if, during the outputting period with the output control signal in activated state, the one-shot pulse is in inactivated state;
the third control circuit when the one-shot pulse is activated during the outputting period with the output control signal in the activated state causing the second transistor to be turned off during the period of activation of the one-shot signal, the third control circuit causing the second transistor to be turned on during the period of inactivation of the one-shot signal,
the third control circuit causing the second transistor to be turned off when the signal to be delivered to the terminal is of a first logic value.

15. The semiconductor device according to claim 14, further comprising:
a circuit that generates the one-shot signal based on a timing control signal generated based on an input command signal, the test signal and a signal delayed from a clock signal.

16. The semiconductor device according to claim 1, wherein the chips each include a semiconductor memory,
a chip select signal out of control signals is separately delivered to each of the chips,
an address signal, a data signal, a clock, a read/write signal and strobe signals of the row address system and the column address system are delivered in common to each of the chips,
read data from the chips are output at a common data terminal, and
the chip select signals of the multiple chips are simultaneously activated at the time of testing to enable the testing.

17. The semiconductor device according to claim 1, wherein the signal output to the terminal of each chip during test is in the form of a compressed signal of a predetermined plural number of data signals; the signal delivered to the terminal assuming a logic value indicating pass or a logic value indicating fail in case the data signals are all coincident or in case at least one or more of the data signals are not coincident.

18. A semiconductor device comprising:
a first chip including a first output circuit which receives a test signal from outside of the first chip, the first output circuit having a first transistor which supplies a first voltage with a first terminal and a second transistor which supplies a second voltage with the first terminal, the first transistor being changed in driving capability thereof in response to the test signal;
a second chip including a second output circuit which receives the test signal from outside of the second chip, the second output circuit having a third transistor which supplies the first voltage with a second terminal and a fourth transistor which supplies a second voltage with the second terminal, the third transistor being changed in driving capability thereof in response to the test signal; and
an external terminal connected with both of the first and second terminal.

19. The semiconductor device according to claim 18, wherein, when a logic level of the test signal is a first level, the driving capability of the first transistor becomes lower than that of the second transistor and the driving capability of the third transistor becomes lower than that of the fourth transistor, and
when the logic level of the test signal is a second level, the driving capability of the first transistor becomes substantially the same as that of the second transistor and the driving capability of the third transistor becomes substantially the same as that of the fourth transistor.
